(19) United States
(12) Patent Application Publication
(10) Pub. No.: US 2012/0135573 A1
(43) Pub. Date: May 31, 2012

(54) METHOD FOR MANUFACTURING VERTICAL TRANSISTOR HAVING ONE SIDE CONTACT

(75) Inventor: Jun Ki KIM, Seoul (KR)

(73) Assignee: HYNIX SEMICONDUCTOR INC., Icheon-si (KR)

(21) Appl. No.: 13/160,689

(22) Filed: Jun. 15, 2011

(30) Foreign Application Priority Data
Nov. 29, 2010 (KR) 10-2010-0119727

(51) Int. Cl. H01L 21/336

(52) U.S. Cl. 438/270; 257/E21.41

(57) ABSTRACT

A method for manufacturing a vertical transistor having a one side contact includes: forming separate active regions using trenches, on a semiconductor substrate, the active regions having first and second side surfaces facing the trenches; forming a first liner on the first and second side surfaces; forming a second liner which exposes a lower portion of the first liner on the first side surface; forming a third liner covering the portion of the first layer exposed by the second liner; forming a sacrifice layer on the third liner to fill the trench; forming an etch barrier to selectively expose upper end portions of the first to third liners positioned adjacent to the first side surface; selectively removing the third liner not covered by the etch barrier to expose a portion of the first liner not covered by the second liner; selectively removing the exposed portion of the first liner to expose a lower portion of the first side surface; and forming a buried bit line contacted with the exposed portion of the first side surface.

### CROSS-REFERENCES TO RELATED APPLICATIONS

The present application claims priority under 35 U.S.C. 119(a) to Korean Application No. 10-2010-0119727, filed on Nov. 29, 2010, in the Korean Intellectual Property Office, which is incorporated herein by reference in its entirety.

### BACKGROUND

Exemplary embodiments of the present invention relate to a semiconductor device, and more particularly, to a method for manufacturing a vertical transistor having a one side contact where a bit line and a junction are contacted with each other.

As the integration degree of semiconductor devices increases, many efforts have been made to integrate a larger number of devices such as transistors within a limited substrate area. In the case of a memory device such as a DRAM device, one transistor and one capacitor form a memory cell capable of handling one bit of data. In order to reduce area occupied by one cell, a vertical transistor structure with a vertical channel provided on a substrate has been proposed.

In such a vertical transistor structure, an active pillar having a vertical channel formed therein may be provided on the substrate, impurity ions may be implanted into the substrate under the channel to form a junction, and the junction may serve as a drain and a bit line. At this time, a source corresponding to the drain is provided at an upper end of the active pillar, and a capacitor is coupled to an upper portion of the source, thereby forming a DRAM cell.

In such a vertical transistor structure, the bit line may be provided as a doped impurity layer to serve as a drain junction. The bit line may be formed in such a shape as to surround a lower end of the active pillar at a portion of the semiconductor substrate adjacent to the lower end of the active pillar. Since the bit line is provided as the impurity layer formed by doping impurities, doped silicon (Si) may exhibit considerably high resistance. Therefore, the bit line exhibits considerably high resistance, which makes it difficult to realize a resistance reduction of the bit line. Furthermore, since the drain junction of the bit line is formed in such a shape as to surround the lower end portion of the active pillar, it is difficult to secure a separation distance from another bit line formed around another adjacent active pillar. When the separation distance between the bit line and another adjacent bit line is small, parasitic capacitance increases between the bit lines. Therefore, when reading out data, the sensing sensitivity of the bit line may be reduced. In order to suppress the parasitic capacitance, a method capable of securing a larger separation distance between the bit line and another adjacent bit line is required. As the integration degree of semiconductor devices increases, a substrate surface area occupied by a memory cell has been considerably reduced, which makes it difficult to secure a sufficient distance between a bit line and another bit line.

### SUMMARY

An embodiment of the present invention relates to a method for manufacturing a vertical transistor having a one side contact where a bit line and a junction contact each other.

In one embodiment, a method for manufacturing a vertical transistor having a one side contact includes: forming separate active regions over a semiconductor substrate, the active regions having first and second side surfaces facing the trenches; forming a first liner on the first and second side surfaces; forming a second liner on the first liner such that the second liner exposes a lower portion of the first liner on the first side surface; forming a third liner covering the portion of the first layer exposed by the second liner and extending to cover the second liner; forming a sacrifice layer on the third liner to fill the trench; forming an etch barrier over the wall bodies and the sacrifice layer to selectively expose upper end portions of the first to third liners positioned adjacent to the first side surface; selectively removing the third liner not covered by the etch barrier to expose the portion of the first liner not covered by the second liner; selectively removing the exposed portion of the first liner to expose a lower portion of the first side surface; and forming a buried bit line contacted with the exposed portion of the first side surface.

In another embodiment, a method for manufacturing a vertical transistor having a one side contact includes: forming separate active regions, over a semiconductor substrate, the active regions having first and second side surfaces facing the trenches; forming a first liner to cover the first and second side surfaces, and bottom portions of the trenches; forming a buried layer by filling the bottom portions of the trenches such that the buried layer does not cover upper portions of the first liner on the first and second side surfaces; forming a second liner to cover the buried layer and the portion of the first liner not covered by the buried layer; exposing the buried layer by anisotropically etching the portion of the second liner on top of the buried layer; recessing the buried layer to expose a lower portion of the first liner; forming a third liner covering the second liner and the lower portion of the first layer not covered by the second liner; forming a sacrifice layer on the third liner to fill the trench; forming an etch barrier over the active regions and the sacrifice layer to selectively expose upper end portions of the first to third liners positioned adjacent to the first side surface; selectively removing the third liner not covered by the etch barrier to expose the portion of the first liner not covered by the second liner; selectively removing the exposed portion of the first liner to expose a lower portion of the first side surface; and forming a buried bit line to be contacted with the exposed portion of the first side surface.

The forming of the separate active regions may include: forming a hard mask over the semiconductor substrate, the hard mask having repetitive lines; and forming the trenches by selectively etching portions of the semiconductor substrate exposed by the hard mask.

The etch barrier may include the hard mask shifted laterally to partially overlap the trench.

The forming of the second liner may include: forming a buried layer to fill the bottom portions of the trenches; forming the second liner over the buried layer such that the second liner covers the first liner not covered by the buried layer; and recessing the buried layer to expose a portion of the first liner below the second liner.

The forming of the buried bit line may include: forming a buried junction by doping impurities into the exposed portion of the first side surface; and forming the buried bit line in the bottom portion of the trench such that the buried bit line is contacted with the buried junction.

The forming of the buried junction may include: forming a doping medium layer, in which impurities are doped, in the bottom portion of the trench such that the doping medium layer is contacted with the exposed portion of the first side surface; and performing a heat treatment on the doping medium layer to diffuse the doped impurities into the exposed portion of the first side surface, thereby forming the buried junction.

The forming the buried bit line may include performing one of: depositing a metal layer on the doping medium layer, and removing the doping medium layer; and depositing a metal layer to be contacted with the buried junction exposed by removal of the doping medium layer.

The forming of the buried junction may include: removing the sacrifice layer and the remaining third liner to expose the second liner; and performing a plasma doping process to provide plasma of As or P to the portion of the first side surface not covered by the first and second liners.

The method may further include: forming division trenches to divide the active regions into a plurality of active pillars such that the division trenches cross the buried bit line; forming a gate dielectric layer on side surfaces of the active pillars exposed to the division trenches; forming a plurality of gates in the division trenches such that the gates cross the buried bit line; and forming an upper junction at an upper end portion of the active pillar that corresponds to the buried junction.

### BRIEF DESCRIPTION OF THE DRAWINGS

The above and other aspects, features and other advantages will be more clearly understood from the following detailed description taken in conjunction with the accompanying drawings, in which:

FIGS. 1 to 15 are diagrams illustrating a method for manufacturing a vertical transistor having a one side contact in accordance with an embodiment of the present invention; and

FIGS. 16 to 21 are diagrams illustrating modifications of the method manufacturing a vertical transistor having a one side contact in accordance with an embodiment of the present invention.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

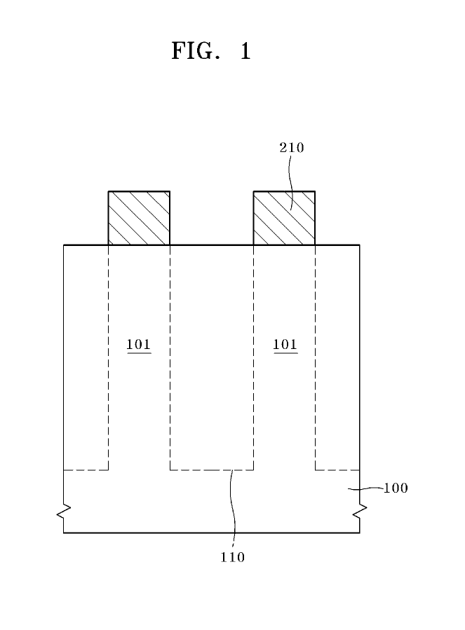

Referring to FIG. 1, a hard mask 210 to be used as an etch mask is formed on a semiconductor substrate 100. In the case of a DRAM device, the hard mask 210 may be formed in such a shape to have repetitive lines extending in a direction where a bit line extends. The hard mask 210 may be used as an etch mask in an etching process for forming first trenches 110 separating active regions 101. The hard mask 210 may be formed including silicon nitride (Si₃N₄) having an etching selectivity with silicon which is a semiconductor material forming the semiconductor substrate 100. The hard mask 210 may be formed to a thickness of approximately 500 Å to 3,000 Å.

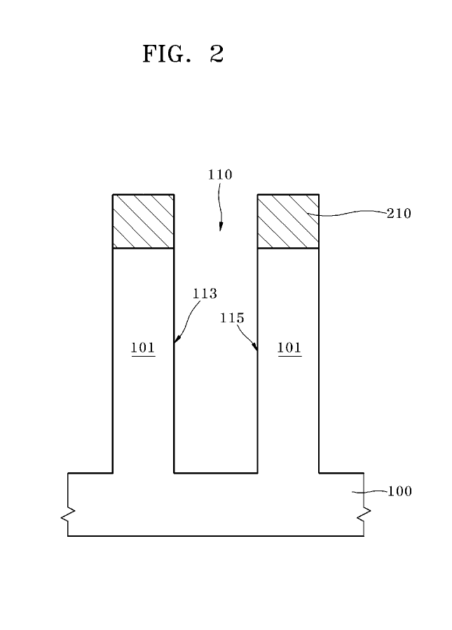

Referring to FIG. 2, portions of the semiconductor substrate 100 exposed by the hard mask 210 are selectively etched to form the first trenches 110 which define the active regions 101. The active regions 101 are formed in such a wall shape as to vertically protrude from the surface of the substrate 100. The active regions 101 are formed to face each other by the first trench 110 formed, and the sidewalls of the trench 101 are formed in such a shape that side surfaces 113 and 115 of the active regions 101 face each other. The left side surface of the active region 101 may be referred to as the side surface 115 and the right side surface of the active region 101 may be referred to as the side surface 113.

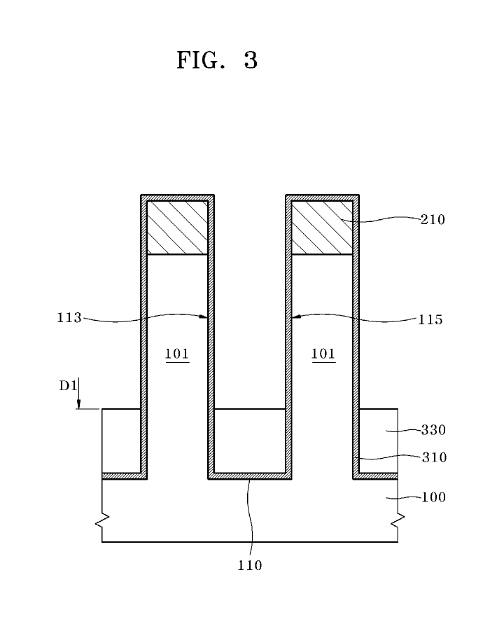

Referring to FIG. 3, a first liner 310 is formed to cover the side surfaces 113 and 115 of the active regions 101 and the bottom of the first trench 110. The first liner 310 is introduced to form a contact mask having an opening which selectively exposes a lower portion of the side surface 113 in a subsequent process. The vertical transistor in accordance with the embodiment of the resent invention may be introduced to form a memory cell of a DRAM device. In this case, the vertical transistor may include a gate provided in a side of the active region of the wall body 101, a buried junction provided in the lower side of the active region, for example, a drain, and a upper junction provided at an upper end portion of the active region and corresponding to the buried junction, for example, a source. Accordingly, the buried junction is contacted and coupled to a buried bit line which is buried in the bottom portion of the first trench 110, and the buried bit line is provided as a one side contact which is contacted with the buried junction as the buried bit line junctions only at the side surface 113. In order to implement such a one side contact, the contact mask having the opening which opens only a portion of the side surface 113 is required.

The first liner 310 may be formed by depositing or thermally oxidizing a layer comprising, for example, silicon oxide (SiO₂). In some cases, the first liner 310 may be formed of silicon nitride to a thickness of approximately 10 Å to 200 Å. The first liner 310 may be introduced as a layer for isolating and insulating the active regions 101 from the buried bit line which will be formed to fill the bottom portion of the first trench 110. A buried layer 330 is formed to fill the first trench 110. The buried layer 330 may be formed by depositing a material layer having an etching selectivity with the first liner 310 such as, for example, polysilicon. In some cases, the buried layer 330 may be formed from, for example, silicon oxide or titanium nitride (TiN).

After the buried layer 330 is deposited, the buried layer 330 is etched and recessed by a first recess process so as to be positioned at the bottom portion of the first trench 110. At this time, the first recess process is performed in such a manner that the upper surface of the recessed buried layer 330 is positioned at a first depth D1 within the first trench 110. The first depth D1 is set according to a position at which the buried junction, to be used as a drain of the vertical transistor, is to be positioned in the active regions 101. When the buried layer 330 is recessed by the first recess process, the first liner 310 may also be partially etched. However, although the first liner 310 may have an etching selectivity with respect to the buried layer 330, the first liner 310 exposed by the first recess process for the buried layer 330 may be partially etched.

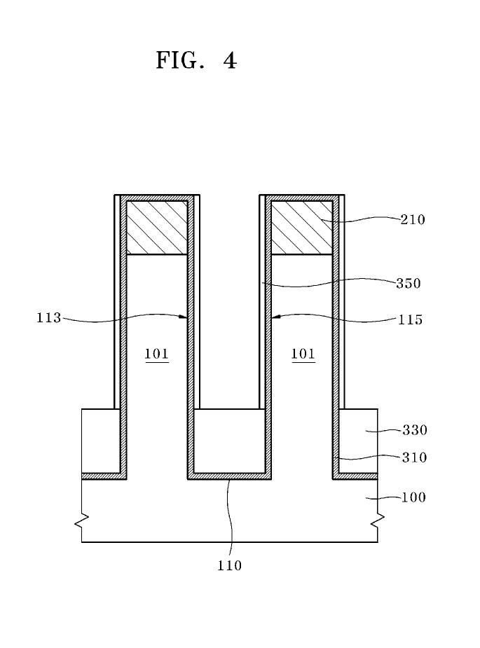

Referring to FIG. 4, a layer for forming a second liner 350 is deposited on the buried layer 330 and portions of the first liner 310 not covered by the buried layer 330. Anisotropic dry etching such as, for example, spacer etching is performed to expose the upper surface of the buried layer 330, thereby forming the second liner 350 covering the exposed portions of the first liner 310. The second liner 350 may be formed, for example, by the following process: a material having an etching selectivity with the first liner 310 such as, for example, silicon nitride having an etching selectivity with silicon oxide being deposited to a thickness of approximately 10 Å to 200 Å. The second liner 350 may then be anisotropically etched to have a spacer shape, that is, where the bottom portion has been removed. In some cases, the second liner 350 may be formed from material comprising silicon oxide.

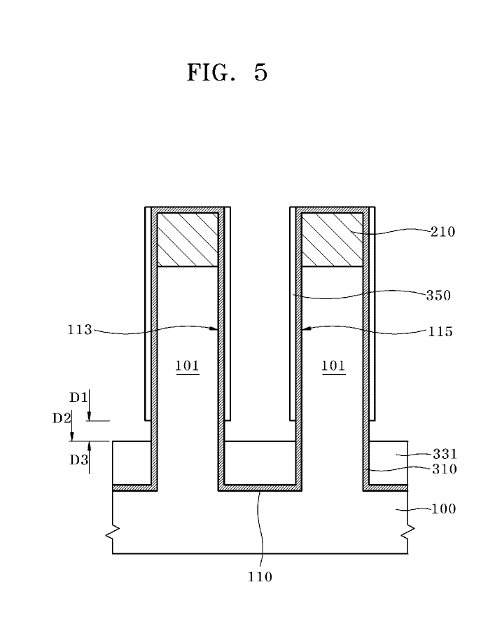

Referring to FIG. 5, the buried layer 330 is recessed by a second recess process such that the upper surface of the buried layer 330 is positioned at a second depth D2. This buried layer may be referred to as buried layer 331. Accordingly, a portion of the first liner 310 corresponding to a difference between the first and second depths D1 and D2 is exposed by the buried layer 331 that was formed from the buried layer 330 recessed by the second recess process. The exposed portion D3 of the first liner 310 corresponds to a portion which is to be one-side etched in a subsequent process to expose a portion of the active region 101 in which a junction is to be formed. Therefore, the exposed portion D3 of the first liner 310 defines the width of the junction corresponding to the drain of the vertical transistor. The first liner 310, the second liner 350, and the buried layer 331 serve as a mask for setting the range of the portion of the active region 101 in which the junction is to be formed.

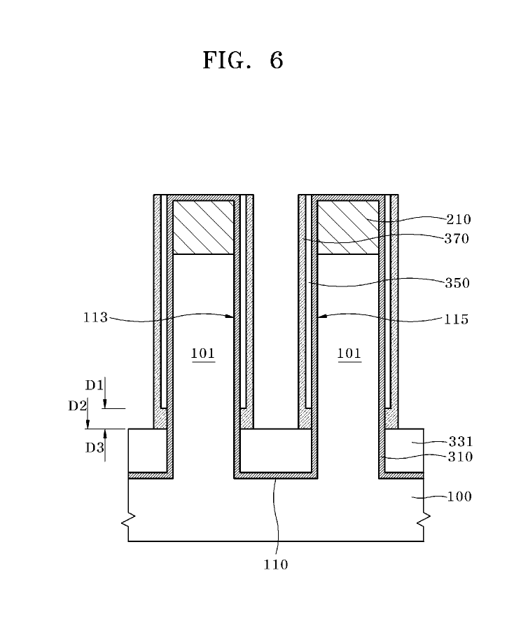

Referring to FIG. 6, third liners 370 are formed to cover the second liner 350 and the exposed portion of the first liner 310. Among the third liners 370, a third liner 370 which is positioned at the side surface 113 of any one of the two active regions 101 facing each other is selectively etched, that is, one-side etched to selectively expose the exposed portion D3 of the first liner 310. Since the second liner 350 needs to be maintained as a mask covering the sidewall of the active region 101, the third liner 370 may be formed from a material having an etching selectivity with the second liner 350 such as, for example, titanium nitride (TiN). The TiN layer is deposited and anisotropically etched to form the third liner 370 in a spacer shape. In some cases, the third liner 370 may be formed from material such as, for example, polysilicon or silicon oxide that have an etching selectivity with the first and second liners 310 and 350 and the buried layer 331. The third liner 370 may be formed to a thickness of, for example, 10 Å to 150 Å.

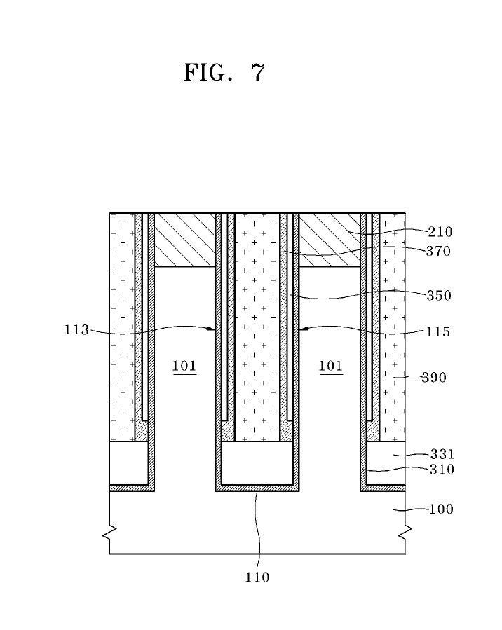

Referring to FIG. 7, a sacrifice layer 390 is formed on the third liner 370 and the buried layer 331 to fill the first trench 110. The sacrifice layer 390 serves as a mask in a one-side etching process in which any one of the two third liners 370 positioned at both sides of the first trench 110 is selected and etched. That is, the sacrifice layer 390 serves as a mask for preventing the unselected third liner 370 from being etched. Therefore, the sacrifice layer 390 may be formed by depositing a material having an etching selectivity with the third liner 370, for example, silicon oxide (SiO₂) and etching back or polishing the deposited material. When the deposited material is polished, a chemical mechanical polishing (CMP) process may be applied. In some cases, the sacrifice layer 390 may be formed from material comprising silicon.

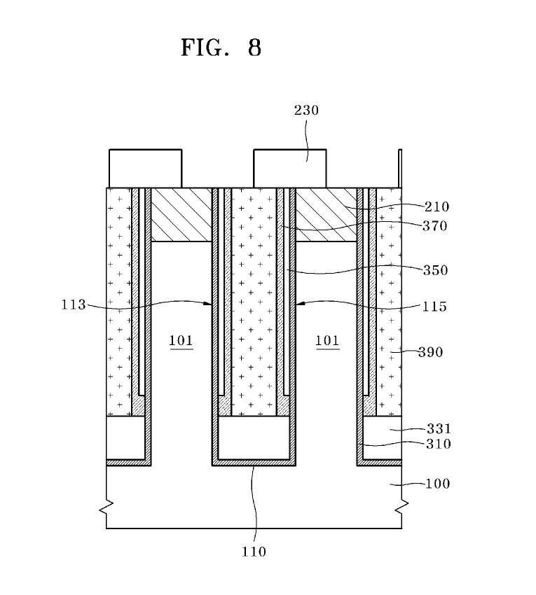

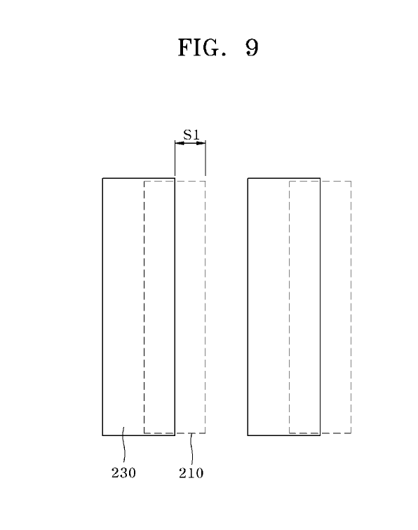

Referring to FIGS. 8 and 9, an etch barrier 230 is formed on the sacrifice layer 390 and the hard mask 210 over the active regions 101. The etch barrier selectively exposes upper end portions of the first to third liners 310, 350, and 370 positioned adjacent to the surface 113 of each active region 101. The etch barrier 230 is formed in such a pattern as to expose upper end portions of the first to third liners 310, 350, and 370 positioned adjacent to the side surface 113 and to block upper end portions of the first to third liners 310, 350, and 370 positioned adjacent to the side surface 115 facing the side surface 113. Such an etch barrier 230 may be formed by the following process: a barrier layer covering the hard mask 210 and the sacrifice layer 390 is formed and then selectively etched to expose a boundary portion of the side surface 113.

The etch barrier 230 may be formed by a photo mask (not shown) which has been used for patterning the hard mask 210. The photo mask may be offset to the side of the hard mask 210 by the distance S, and then used for selectively exposing and etching the etch barrier 230. Accordingly, the etch barrier 230 may be set such that it is shifted to partially overlap the first trench 110. Accordingly, a lithography process in which the same photo mask is used to selectively expose and etch the hard mask 210 and the etch barrier 230 may be performed, which makes it possible to omit a process of manufacturing an additional photo mask.

In order to suppress the damage of the hard mask 210 while forming the etch barrier 230, the etch barrier 230 may be formed by depositing a material having an etching selectivity with the hard mask 210 formed of silicon nitride such as, for example, silicon or silicon oxide to a thickness of approximately 50 Å to 300 Å. When the etch barrier 230 is formed with, for example, silicon oxide, the etch barrier 230 may also be removed when the silicon oxide forming the sacrifice layer 390 is etched and removed. Since the etch barrier 230 may be removed together with the sacrifice layer 390, a separate etching process for removing the etch barrier 230 may not be needed.

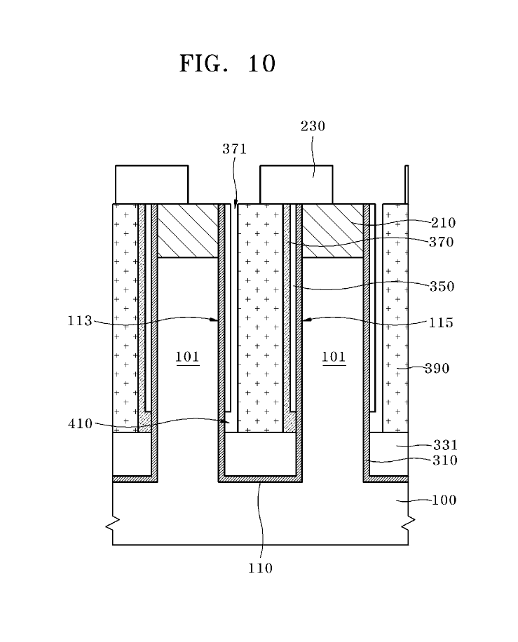

Referring to FIG. 10, the third liner 370 not covered by the etch barrier 230 is selectively etched and removed. Since the etch barrier 230 exposes the selected third liner 370 at the side surface 113 and blocks the unselected third liner 370 at the side surface 115 on the opposite side, the one-side etching process is performed to etch and remove only the exposed third liner 370. When the third liner 370 is formed with material comprising TiN, the third liner 370 may be selectively removed by a wet etching process using a wet etchant such as, for example, a mixture of H₂SO₄ and H₂O₂. Accordingly, an open path 371 having a groove shape is formed at the interface between the sacrifice layer 390 and the second liner 350, and a portion of the first liner 310 is exposed to a bottom portion of the open groove 371. The portion of the first liner 310 exposed by the groove 371 corresponds to the portion D2 exposed between the second liner 350 and the buried layer 331 in FIG. 5. After the third liner 370 is selectively removed, the exposed portion of the first liner 310 is selectively etched and removed to form an opening 410 which exposes a portion of the active region 101 in which a junction is to be formed.

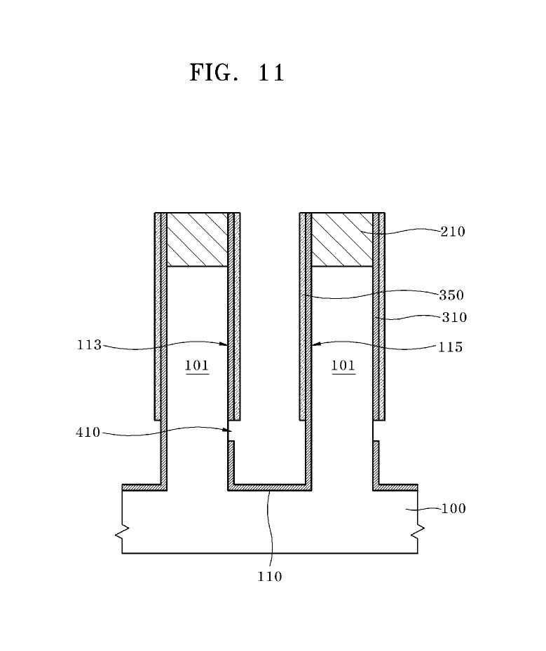

Referring to FIG. 11, an etching process is performed to remove the sacrifice layer 390. The sacrifice layer 390 and the first liner 310 may be formed from substantially the same material such as, for example, silicon oxide such that the exposed portion of the first liner 310 is removed with the sacrifice layer 390. Accordingly, a separate etching process for forming the opening portion may not be needed. Furthermore, since the etch barrier 230 may be made of similar material as the sacrifice layer 390, the etch barrier 230 may also be removed by a wet oxide etchant used for removing the sacrifice layer 390.

After the sacrifice layer 390 is etched and removed, the third liner 370 remaining over the side surface 115 opposite the side surface 113 is also etched and removed. Then, the buried layer 331 positioned in the bottom portion of the first trench 110 is also selectively removed. Alternatively, when the buried layer 331 is a metal layer or a conductive layer which may be used as a portion of a subsequent bit line, the buried layer 331 may be left and used as a portion of the bit line. The first liner 310 remaining on the bottom of the first trench 110, the second liner 350, and the opening 410 at the lower portion of the side surface 113 may form a contact mask for forming a buried junction. The opening 410 is positioned at the lower portion of the active region 101, and spaced a predetermined distance from the bottom of the first trench 110 in consideration of the position in which a buried bit line is to be formed.

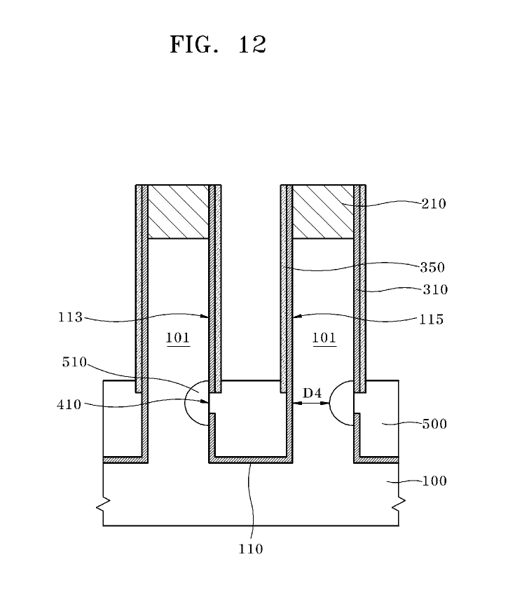

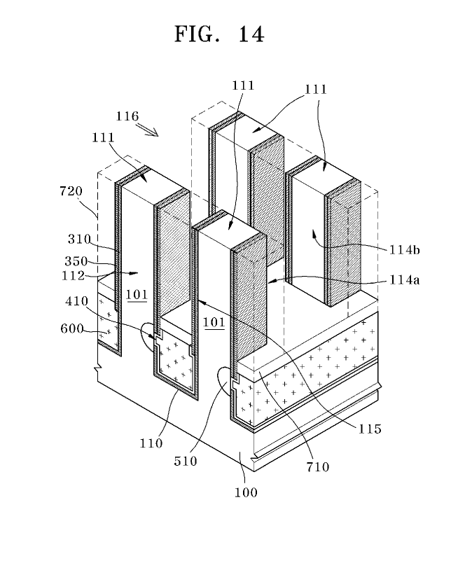

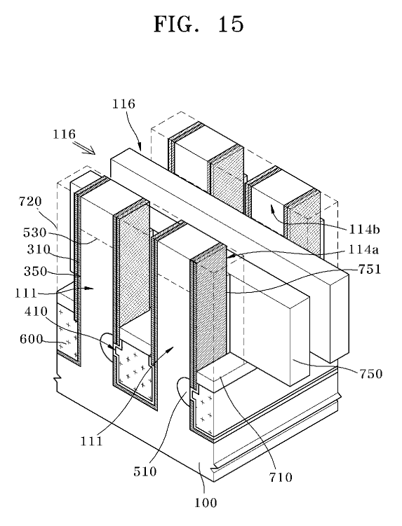

Referring to FIG. 12, impurities are doped through the opening 410 to form a buried junction 510 which is to be coupled to a bit line. Such a buried junction 510 is used as a contact junction which is contacted with the bit line, and may be used as a drain of the vertical transistor. The buried junction 510 is formed by doping impurities, and requires a considerably high doping concentration to reduce contact resistance with a buried bit line contacted with the buried junction 510. However, the buried junction 510 needs to have a diffusion profile extending to such a depth (or distance) that is required for the buried junction 510 to operate as a drain. For example, the side surface 115 and the profile bottom of the buried junction 510 are separated from each other by a distance D4, thereby implementing a body tied structure in which a portion of the active region 101 under the channel and the semiconductor substrate 100 are not blocked but connected to each other. Accordingly, hole charges generated in the channel may escape toward the semiconductor substrate 100 through the separated portion, thereby effectively suppressing the hole charges from being piled up. That is, it is possible to efficiently suppress a floating body effect. The source, gate, and drain will be discussed in more detail with respect to FIGS. 14 and 15.

The impurity doping may be performed by a variety of methods. A doping medium layer 500 such as a polysilicon layer in which impurities are doped is deposited in the first trench 110, and the impurities are diffused by annealing to form the junction 510. The doping medium layer 500 may be performed by depositing a polysilicon layer in which, for example, arsenic (As) or phosphorus (P) is doped, and the buried junction 510 may be formed by diffusing the impurities through a rapid thermal annealing (RTA) process. At this time, a polysilicon layer may be first deposited and then recessed to reduce its thickness, and the impurities may be then doped by ion-implanting As or P.

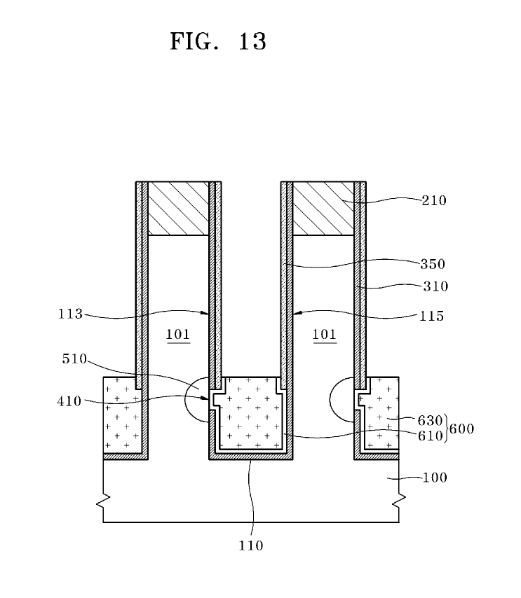

Referring to FIG. 13, after the buried junction 510 is formed, a buried bit line 600 contacted with the buried junction 510 is formed. The buried bit line 600 is formed by the following process: the doping medium layer 500 is selectively removed, and a metal layer 630 such as a bit line conductive layer such as, for example, a TiN layer is then deposited in the first trench 110 and recessed to form the buried bit line 600. The metal layer 630 may include, for example, a TiN layer or tungsten (W) layer. At the interface between the metal layer 630 and the buried junction 510, a silicide layer such as TiSiₓ or a compound layer including Ti and TiN may be introduced as an interface layer 610, when the metal layer 630 is formed of W. The buried bit line 600 is contacted with the buried junction 510 through the opening 410. At this time, a one side contact is formed in which contact is only in a one-side sidewall direction of the active region 101.

A metal layer may also be deposited on the doping medium layer 500 of FIG. 12 and then used as a portion of the buried bit line 600. Since the doping medium layer 500 may comprise a doped polysilicon layer, a low-resistance metal layer such as W for reducing resistance may be additionally deposited to form the bit line.

Referring to FIG. 14, after the buried bit line 600 forming a one side contact is formed, a first insulation layer 710 for insulating the buried bit line 600 is formed inside the first trench 110. The first insulation layer 710 may be formed including a silicon nitride (Si₃N₄) layer. On the first insulation layer 710, a second insulation layer 720 is formed to fill the first trench 110. The second insulation layer 720 may be formed by applying spin on dielectric (SOD) such as, for example, polysilazane, and densifying the SOD through a heat treatment. At this time, a high density plasma (HDP) oxide layer may be further formed on the SOD layer and used as a layer for fixing the SOD layer. That is, the second insulation layer 720 may be formed as a dual layer including the SOD layer and the HDP oxide layer.

Then, a second trench 116 is formed as a division trench which separates the active regions 101. The second trench 116 divides the active regions 101 into unit cells by forming active pillars 111.

Referring to FIG. 15, the second trench 116 is formed to cross the buried bit line 600, and formed to expose side surfaces 114 of the active pillars 111 on which gates 750 used as word lines are to be formed. At this time, the first insulation layer 710 or the second insulation layer 720 may partially remain on the bottom of the second trench 116 so as not to expose the buried bit line 600. The side surface 114a of the active pillar 111 exposed by the second trench 116 is formed to have a plane direction crossing the side surface 113 and the side surface 115. On the exposed side surface 114a, a gate dielectric layer 751 is formed by performing thermal oxidation or the like.

On the gate dielectric layer 751 inside the second trench 116, a word line 750 is formed. At this time, the gate 750 is formed in a shape attached in the side direction on the gate dielectric layer 751, and may include a metal layer such as a W layer. At this time, a layer for the gate 750 may be deposited in order to form separate gates 750 on the side surfaces 114a and 114b facing each other, and an anisotropic dry etching process may be performed to expose the bottom of the second trench 116. Through the dry etching process, the gate 750 may be separated in such a shape that the active pillars 111 are attached to each of the separated gates 750. At the interface between the W layer and the gate dielectric layer 751, a Ti/TiN layer may be introduced as an adhesive layer. The gate 750 is formed to extend in a direction crossing the buried bit line 600. After the layer for the gate 750 is deposited and recessed to expose the side surfaces of the upper end portions of the active pillars 111, impurities, for example, P may be doped via the exposed upper end portions of the active pillars 111 to form a source 530. As such, the vertical transistor may be formed, and capacitors are integrated to be coupled to the source 530, thereby forming a DRAM memory cell.

The method for manufacturing the vertical transistor having a one side contact in accordance with an embodiment of the present invention may be modified to increase an open margin at which the etch barrier 230 exposes the third liner 370. For example, as the upper end portion of the third liner 370 is positioned more adjacent to the hard mask 210, it is possible to increase an overlay margin when the etch barrier 230 is formed. Although the width of the first trench 110 is reduced as the design rule of semiconductor devices shrinks, a larger separation distance may be secured between the end portions of the two third liners 370 facing each other and positioned on the side surfaces 113 and 115 of the first trench 110. Therefore, it is possible to secure a larger open margin when the etch barrier 230 is formed to selectively expose only the upper end portion of one third liner 370 positioned at the first side surface 113.

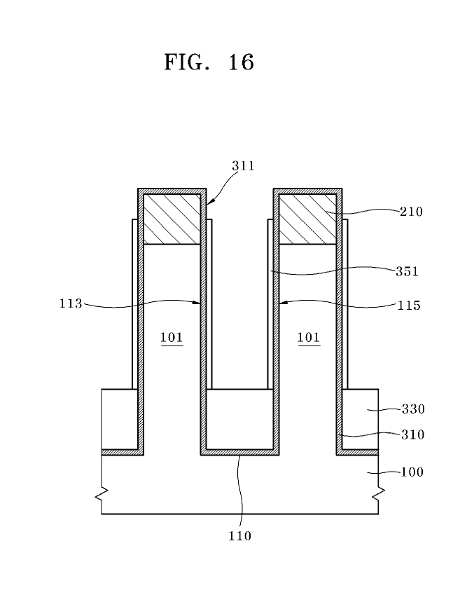

After the second liner 350 is formed as described with reference to FIG. 4, the second liner 350 is anisotropically etched, that is, an upper portion of the second liner 350 is partially etched and removed to expose a portion of the side surface of the upper end portion of the first liner 310, as illustrated in FIG. 16. This etched second liner 350 may be referred to as second liner 351. As described above with reference to FIG. 4, a layer for the second liner 351 is deposited on the buried layer 330 and the portion of the first liner 310 exposed by the buried layer 330, and an anisotropic dry etching process such as spacer etching is performed to expose the upper surface of the buried layer 330 such that the second liner 351 covers the first liner 310. At this time, when spacer etching is additionally performed, the upper portion of the second liner 350 is continuously etched, and the etched second liner 351 is formed in such a manner as to expose the side surface of the upper end portion of the first liner 310. At this time, depending on how much the second liner 351 is etched, a distance 311 at which the side surface of the upper end portion of the first liner 310 is exposed may differ. At this time, the second liner 351 is additionally etched in such a manner that the distance 311 approaches about 100 Å or more.

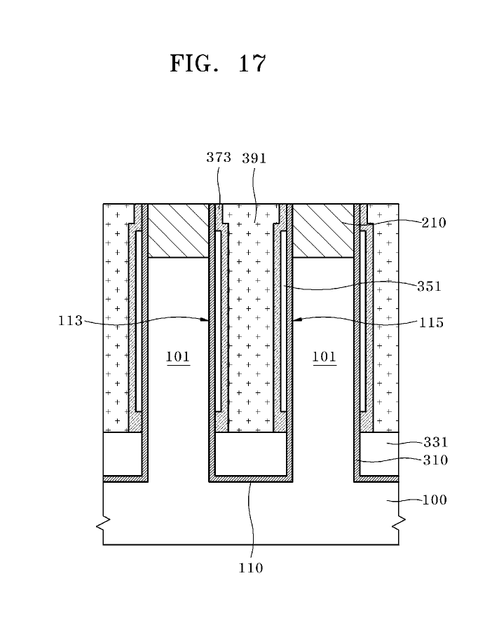

Referring to FIG. 17, the buried layer 330 is recessed by the second recess process such that the upper surface thereof is positioned at the second depth D2 as described with reference to FIG. 5. Accordingly, the lower end portion of the first liner 310 is partially exposed by the buried layer 331 recessed by the second recess process. As a result, the second liner 351 is formed to partially expose the upper and lower end portions of the first liner 310. Then, as described with reference to FIG. 6, third liners 373 are formed. At this time, the third liner 373 is formed to cover the upper and lower end portions of the first liner 310 exposed by the second liner 351. As described with reference to FIG. 7, a sacrifice layer 391 is formed. Since the second liner 351 is formed to expose the portion of the side surface of the upper end portion of the first liner 310, the third liner 373 is formed to be directly contacted with the side surface of the upper end portion of the first liner 310. Therefore, upper end portions of the two third liners 373 formed at the first and second side surfaces 113 and 115 of the active regions 101, respectively, are positioned separately from each other while having a larger separation distance.

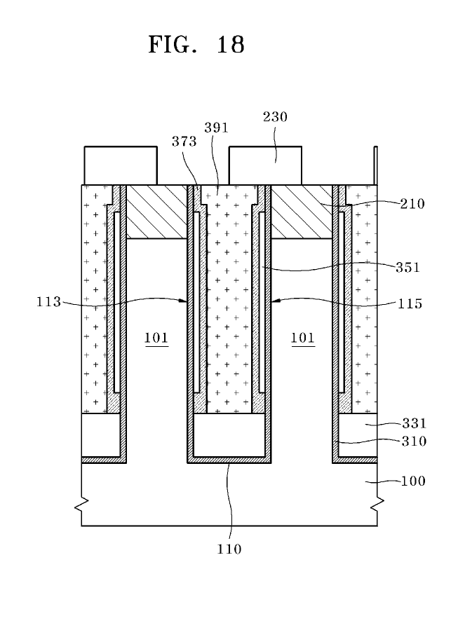

Since the upper end portions of the two third liners 373 facing each other are positioned separately from each other while having a larger separation distance, it is possible to secure a larger overlap margin of the etch barrier 230, when the etch barrier 230 is formed as illustrated in FIG. 18. More specifically, when the etch barrier 230 is formed to overlap the sacrifice layer 391 and the hard mask 210 such that only the upper end portion of the third liner 373 at the first side surface 113 is selectively exposed, a larger overlap margin may be secured. The etch barrier 230 needs to be patterned in such a manner that a pattern sidewall of the etch barrier 230 is positioned at the sacrifice layer 391 between the upper end portions of the two third liners 373 facing each other. When the width of the sacrifice layer 391 is too small, it is difficult to form the etch barrier 230 such that the etch barrier 230 is positioned to overlap the sacrifice layer 391 and the hard mask 210 at an exact position. Since the upper end portion of the second liner 351 is not exposed but buried under the third liner 373 as illustrated in FIG. 18, the width of the sacrifice layer 391 is increased by a value two times larger than the width of the second liner 350, compared with the case illustrated in FIG. 8. Therefore, it may become easy to position the etch barrier to overlap the wider upper surface of the sacrifice layer 391. Therefore, it is possible to secure a larger overlap margin for the etch barrier 230.

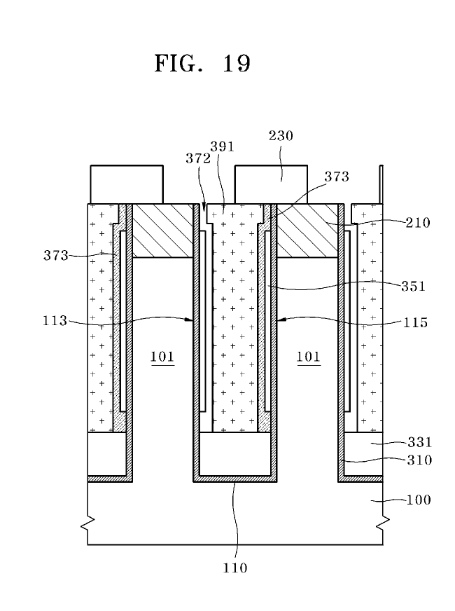

Referring to FIG. 19, the third liner 373 exposed to the etch barrier 230 is selectively removed to form a groove 372 and an opening 410, as described above with reference to FIG. 10. Then, the sacrifice layer 391 and the remaining third liner 373 are removed as described with reference to FIG. 11.

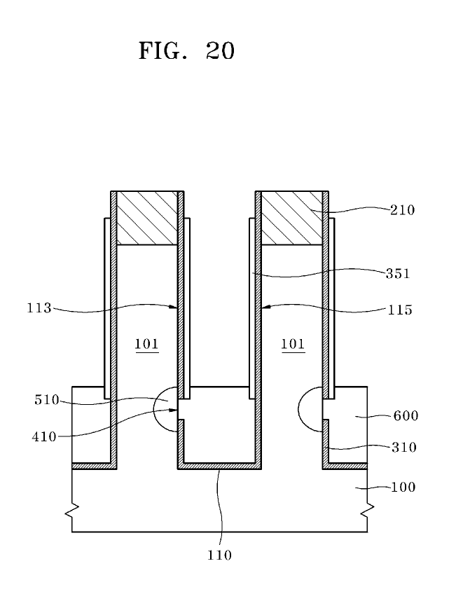

Referring to FIG. 20, a buried junction 510 and a buried bit line 600 may be formed as described with reference to FIGS. 12 and 13. Then, the vertical transistor structure may be formed as described with reference to FIGS. 14 and 15.

Meanwhile, when the buried junction 510 is formed as illustrated in FIG. 12, the doping medium layer 500 may not be introduced, but impurities may be directly diffused into the exposed portion of the first side surface 113 through the opening 410.

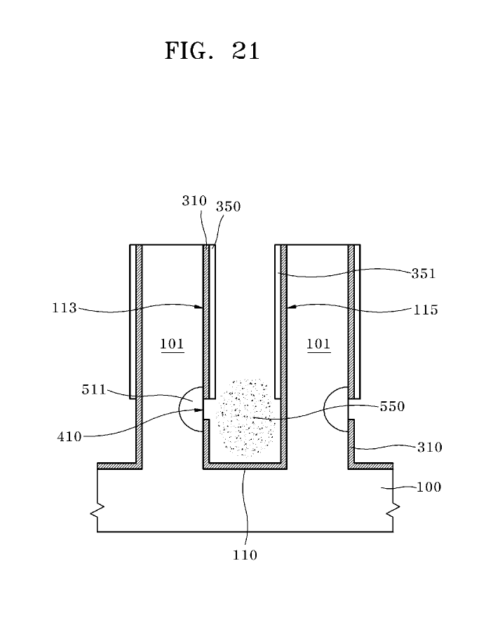

Referring to FIG. 21, plasma doping is performed to provide As or P plasma 550 to the portion of the first side surface 113 exposed to the opening 410. Then, impurities such as P or As may be diffused to the active region inside the exposed portion of the first side surface 113 from the plasma 550. As such, the buried junction 511 may be formed by plasma doping.

In accordance with an embodiment of the present invention, it is possible to provide a method for manufacturing a vertical transistor having a one side contact which exposes a portion of one side surface of two facing side surfaces of two active regions as a junction such that the junction is contacted with a buried bit line.

The embodiments of the present invention have been disclosed above for illustrative purposes. Those skilled in the art will appreciate that various modifications, additions, and substitutions are possible, without departing from the scope and spirit of the invention as disclosed in the accompanying claims.

What is claimed is:

1. A method for manufacturing a vertical transistor having a one side contact, comprising:
forming separate active regions, on a semiconductor substrate, with trenches, the active regions having first and second side surfaces facing the trenches;
forming a first liner on the first and second side surfaces;
forming a second liner on the first liner such that the second liner exposes a lower portion of the first liner on the first side surface;
forming a third liner covering the portion of the first layer exposed by the second liner and extending to cover the second liner;
forming a sacrifice layer on the third liner to fill the trench;
forming an etch barrier over the wall bodies and the sacrifice layer to selectively expose upper end portions of the first to third liners positioned adjacent to the first side surface;
selectively removing the third liner not covered by the etch barrier to expose the portion of the first liner not covered by the second liner;
selectively removing the exposed portion of the first liner to expose a lower portion of the first side surface; and
forming a buried bit line contacted with the exposed portion of the first side surface.

2. The method of claim 1, wherein forming the separate active regions comprises:
forming a hard mask over the semiconductor substrate, the hard mask having repetitive lines; and
forming the trenches by selectively etching portions of the semiconductor substrate exposed by the hard mask.

3. The method of claim 2, wherein the etch barrier comprises the hard mask shifted laterally to partially overlap the trench.

4. The method of claim 2, wherein the etch barrier comprises a material with an etching selectivity with the hard mask.

5. The method of claim 4, wherein the etch barrier, comprising one of silicon and silicon oxide, is made of the same material as the sacrifice layer, and the hard mask is formed including silicon nitride having an etching selectivity with the silicon oxide.

6. The method of claim 1, wherein the first to third liners comprise at least one of: silicon oxide, silicon nitride, polysilicon, and titanium nitride (TiN) to have an etching selectivity with one another.

7. The method of claim 6, wherein the first and second liners comprise silicon oxide or silicon nitride to have an etching selectivity with each other and have an etching selectivity with the third liner.

8. The method of claim 6, wherein the third liner comprises polysilicon or titanium nitride to have an etching selectivity with the first and second liners.

9. The method of claim 1, wherein the forming of the second liner comprises:
forming a buried layer to fill the bottom portions of the trenches;
forming the second liner over the buried layer such that the second liner covers the first liner not covered by the buried layer; and
recessing the buried layer to expose a portion of the first liner below the second liner.

10. The method of claim 9, wherein the buried layer comprises at least one of: polysilicon, silicon oxide, and titanium nitride to have an etching selectivity with the first to third liners.

11. The method of claim 1, wherein the forming of the buried bit line comprises:
forming a buried junction by doping impurities into the exposed portion of the first side surface; and
forming the buried bit line in the bottom portion of the trench such that the buried bit line is contacted with the buried junction.

12. The method of claim 11, wherein the forming of the buried junction comprises:
forming a doping medium layer, in which impurities are doped, in the bottom portion of the trench such that the doping medium layer is contacted with the exposed portion of the first side surface; and
performing a heat treatment on the doping medium layer to diffuse the doped impurities into the exposed portion of the first side surface, thereby forming the buried junction.

13. The method of claim 12, wherein the doping medium layer is formed by performing one of the following: including a polysilicon layer in which P or As is doped as the impurities, and forming a one side contact by depositing and recessing the polysilicon layer and ion-implanting P or As.

14. The method of claim 12, wherein the buried bit line is formed by performing one of: depositing a metal layer on the doping medium layer, and removing the doping medium layer and depositing a metal layer to be contacted with the buried junction exposed by removal of the doping medium layer.

15. The method of claim 11, wherein the forming of the buried junction comprises:
removing the sacrifice layer and the remaining third liner to expose the second liner; and
performing a plasma doping process to provide plasma of As or P to the portion of the first side surface not covered by the first and second liners.

16. The method of claim 11, further comprising:
forming division trenches to divide the active regions into a plurality of active pillars such that the division trenches cross the buried bit line;
forming a gate dielectric layer on side surfaces of the active pillars exposed to the division trenches;
forming a plurality of gates in the division trenches such that the gates cross the buried bit line; and
forming an upper junction at an upper end portion of the active pillar that corresponds to the buried junction.

17. A method for manufacturing a vertical transistor having a one side contact, comprising:
forming separate active regions, over a semiconductor substrate, with trenches, the active regions having first and second side surfaces facing the trenches;
forming a first liner to cover the first and second side surfaces and bottom portions of the trenches;
forming a buried layer by filling the bottom portions of the trenches such that the buried layer does not cover upper portions of the first liner on the first and second side surfaces;
forming a second liner to cover the buried layer and the portion of the first liner not covered by the buried layer;
exposing the buried layer by anisotropically etching the portion of the second liner on top of the buried layer;
recessing the buried layer to expose a lower portion of the first liner;
forming a third liner covering the second liner and the lower portion of the first layer not covered by the second liner;
forming a sacrifice layer on the third liner to fill the trench;
forming an etch barrier over the active regions and the sacrifice layer to selectively expose upper end portions of the first to third liners positioned adjacent to the first side surface;
selectively removing the third liner not covered by the etch barrier to expose the portion of the first liner not covered by the second liner;
selectively removing the exposed portion of the first liner to expose a lower portion of the first side surface; and
forming a buried bit line to be contacted with the exposed portion of the first side surface.

18. The method of claim 17, wherein the forming of the separate active regions comprises:
forming a hard mask over the semiconductor substrate, the hard mask having repetitive lines; and
forming the trenches by selectively etching portions of the semiconductor substrate exposed by the hard mask, wherein
the second liner exposes a portion of the first liner covering the upper side surface of the hard mask with an anisotropic etching process.

19. The method of claim 17, wherein the etch barrier is formed by shifting the hard mask laterally to overlap the trench.

20. The method of claim 17, wherein the etch barrier comprises silicon oxide to have an etching selectivity with silicon nitride forming the hard mask, and have the same etch rate as silicon oxide forming the sacrifice layer.
